(19) United States
(12) Patent Application Publication
(10) Pub. No.: US 2022/0242723 A1
(43) Pub. Date: Aug. 4, 2022

(54) PHYSICAL QUANTITY SENSOR AND SEMICONDUCTOR DEVICE

(71) Applicant: DENSO CORPORATION, Kariya-city (JP)

(72) Inventors: Kazuaki MAWATARI, Kariya-city (JP); Keisuke KUROKAWA, Kariya-city (JP)

(21) Appl. No.: 17/724,718

(22) Filed: Apr. 20, 2022

Related U.S. Application Data
(62) Division of application No. 17/022,476, filed on Sep. 16, 2020.
Application No. 17/022,476 is a division of application No. 16/266,159, filed on Feb. 4, 2019, now abandoned.

(30) Foreign Application Priority Data
Feb. 20, 2018 (JP) 2018-27846

(51) Int. Cl. B81B 7/00; H01L 23/00

(52) U.S. Cl. CPC B81B 7/0048; H01L 24/73; H01L 2224/73265; H01L 2924/1461; H01L 2924/351

(57) ABSTRACT

A device includes: a chip; a support member; an adhesive layer disposed on the support member; and a wire electrically connected to the sensor chip on a side face of the sensor chip. Herein the adhesive layer includes a material exhibiting a dilatancy property in which a shear stress increases in a multi-dimensional function as a shear rate increases.

### CROSS REFERENCE RELATED APPLICATION

The present application claims the benefit of priority from Japanese Patent Application No. 2018-27846 filed on Feb. 20, 2018. The entire disclosure of the above application is incorporated herein by reference.

### TECHNICAL FIELD

The present disclosure relates to a physical quantity sensor and a semiconductor device.

### BACKGROUND

There is conventionally known a physical quantity sensor which includes (i) a sensor chip having a sensor part for outputting a signal corresponding to a physical quantity, (ii) a support member on which the sensor chip is mounted, (iii) an adhesive layer disposed on the support member and supporting the sensor chip, and (iv) a wire to be electrically connected to the sensor chip.

### SUMMARY

According to an example of the present disclosure, a device is provided to include (i) a chip, (ii) a support member, (iii) an adhesive layer disposed on the support member, and (iv) a wire electrically connected to the chip. The adhesive layer includes a material exhibiting a dilatancy property in which a shear stress increases in a multi-dimensional function as a shear rate increases.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a schematic cross-sectional view showing a cross section of a physical quantity sensor according to a first embodiment;

FIG. 2 is a schematic diagram illustrating a dilatancy property of a modified adhesive layer, and a relation of a shear stress or viscosity against a shear rate;

FIG. 3 is a schematic cross-sectional view showing a cross section of a physical quantity sensor according to a second embodiment;

FIG. 4 is a schematic cross-sectional view showing a cross section of a physical quantity sensor according to a third embodiment;

FIG. 5 is a schematic cross-sectional view showing a cross section of a physical quantity sensor according to a fourth embodiment;

FIG. 6 is a schematic cross-sectional view showing a cross section in a modified example of the physical quantity sensor of the fourth embodiment;

FIG. 7 is a schematic cross-sectional view showing a cross section of a physical quantity sensor according to a fifth embodiment;

FIG. 8 is a schematic cross-sectional view showing a cross section in a modified example of the physical quantity sensor of the fifth embodiment; and

FIG. 9 is a schematic cross-sectional view showing a cross section of a physical quantity sensor according to another embodiment.

### DETAILED DESCRIPTION

Hereinafter, embodiments of the present disclosure will be described with reference to the drawings. The following embodiments will be described with the same or equivalent parts denoted by the same reference signs.

### First Embodiment

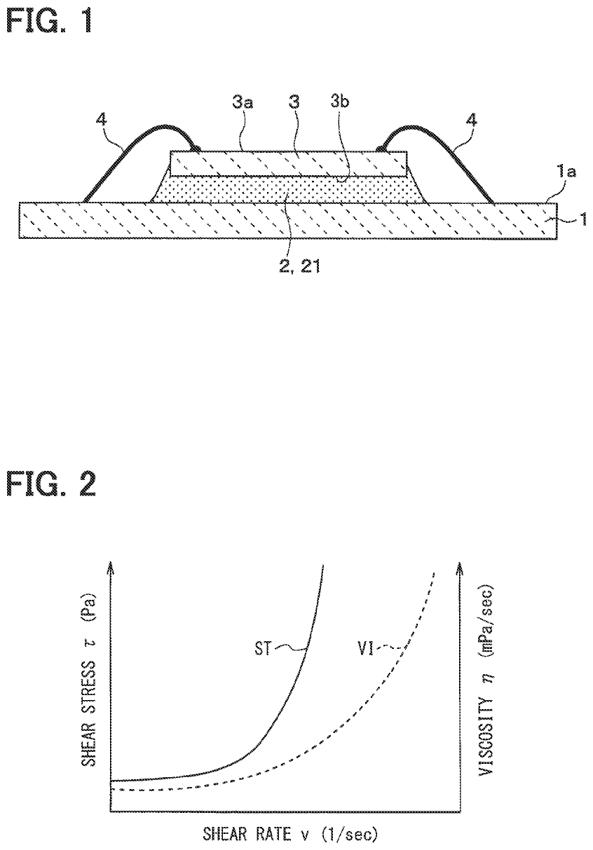

A physical quantity sensor according to a first embodiment will be described with reference to FIGS. 1 and 2. The physical quantity sensor of this embodiment is applied to, for example, a physical quantity sensor mounted in a vehicle such as an automobile to output a signal corresponding to a physical quantity applied to the vehicle or its constituent parts.

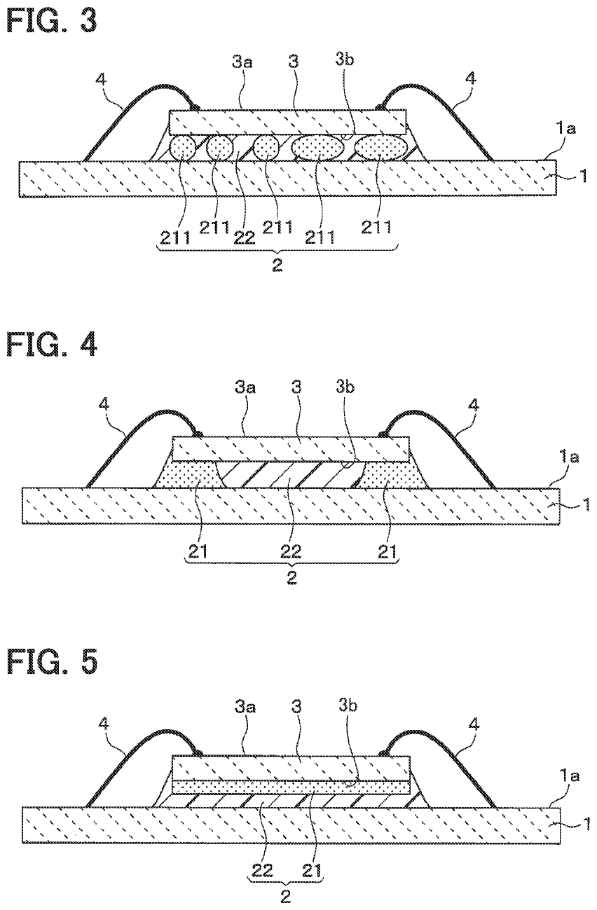

In FIG. 1, in order to make the configuration of the physical quantity sensor easier to understand, the thickness and dimensions are exaggerated and deformed. Furthermore, for easily understanding, the upper side of FIG. 1 may be described as the upper side or front side of the physical quantity sensor; the lower side of FIG. 1 may be described as the lower side or back side of the physical quantity sensor. This may be applied to other drawings of FIGS. 3 to 9. In FIG. 2, in order to make it easy to see, the shear stress (ST) of the modified adhesive layer 21 is indicated by a solid line and the viscosity (VI) of the modified adhesive layer 21 is indicated by a broken line.

As shown in FIG. 1, the physical quantity sensor of this embodiment includes a support member 1, an adhesive layer 2, a sensor chip 3, and a wire 4. The physical quantity sensor is configured to output, to the wire 4, a signal corresponding to the physical quantity acting on the sensor chip 3.

As shown in FIG. 1, the support member 1 is a support having a front side face 1a (which may be also referred to a surface 1a). The sensor chip 3 is mounted on the front side face 1a of the support member 1 via the adhesive layer 2. The support member 1 is configured in a form such as a substrate, a lead frame, a housing part, etc., and is made of a predetermined material such as a resin material or a conductive metallic material, depending on an intended use of the physical quantity sensor. For example, when the physical quantity sensor of this embodiment is configured to be a pressure sensor, the support member 1 may be a resin molded body including resin material, or may be a housing made of metal material.

As shown in FIG. 1, the adhesive layer 2 is a layer disposed on the front side face 1a of the support member 1 for mounting the sensor chip 3 on the support member 1, and is formed with, for example, a dispenser or the like. The adhesive layer 2 includes a material, which exhibits a low elasticity when a slow shear stimulus, i.e., a slow external force is applied whereas exhibiting a high elasticity when a faster shear stimulus, e.g., a sudden external force is applied. That is, the adhesive layer 2 includes a material exhibiting a dilatancy property.

Specifically, the adhesive layer 2 exhibits a high elasticity in a state where a fast shear stimulus such as wire bonding of the wire 4 to the sensor chip 3 described later is applied, and exhibits a low elasticity in a state where a slow shear stimulus such as thermal stress is applied after the connection of the wire 4. In other words, the adhesive layer 2 has a material exhibiting a dilatancy property in which the elastic modulus in the wire bonding of the wire 4 to the sensor chip 3 is higher than the elastic modulus after the connection of the wire 4 to the sensor chip 3.

Here, “high elasticity” signifies that its elastic modulus is 100 MPa to 30 GPa, and “low elasticity” signifies that its elastic modulus is 0.1 MPa to 10 MPa.

In the present embodiment, as shown in FIG. 1, the adhesive layer 2 is configured to include a dilatant fluid exhibiting the above dilatancy property, and the whole of the adhesive layer 2 is made as a modified adhesive layer 21 exhibiting a dilatancy property. In the present embodiment, the adhesive layer 2 is made of a mixture of a high elasticity material exhibiting a high elasticity and a low elasticity material exhibiting a low elasticity.

For example, (i) an inorganic material such as SiO₂ and/or (ii) an organic material of a thermoplastic resin such as polyethylene, and/or a thermosetting resin such as phenol resin may be used as a high elasticity material. On the other hand, an organic adhesive material such as silicone, polyacrylate, perfluoropolyether may be used as a low elasticity material. In this case, the high elasticity material is, for example, granular material with a grain diameter of 10 μm or more in order to exhibit the dilatancy property in the mixture. In addition, in order to secure a wide area exhibiting a dilatancy property in the mixture, it is preferable that the highly elasticity material is contained in an amount of 50 vol % or more with respect to the entire mixture. Specifically, for example, the adhesive layer 2 may employ a material in which a high elasticity material such as SiO₂ and a low elasticity material such as silicone are mixed in an emulsion such as a vinyl acetate resin type or an epoxy resin type, and a high elasticity material is contained by 50 vol % or more.

For example, as described above, the modified adhesive layer 21 is made of a material having high elasticity and low elasticity and satisfying the following Expressions (1) and (2), that is, having a dilatancy property.

τ=μ×vⁿ (1)

η=μ×v⁽ⁿ⁻¹⁾ (2)

In Expression (1) or Expression (2), τ is a shear stress (unit: Pa) generated in the mixture, v is a shear rate (unit: sec−1) generated in the mixture, and η is a viscosity (Unit: Pa×sec) in the mixture. Also, μ is a constant, while n is a number greater than 2 (two). That is, as shown in FIG. 2, the modified adhesive layer 21 has such a property that as the shear rate applied to the modified adhesive layer 21 increases (i.e., as the shear stimulus becomes faster), the viscosity η of the modified adhesive layer 21 and the shear stress τ generated in the modified adhesive layer 21 increase in a multi-dimensional function. The effect of this modified adhesive layer 21 will be described later.

As shown in FIG. 1, for example, the sensor chip 3 is formed in a rectangular plate shape having one side face 3a (which may be referred to as a first side face), to be disposed so that an opposite side face 3b (which may be referred to as a second side face or the other one side face) that is opposite the one side face 3a is in contact with the adhesive layer 2; the sensor chip 3 is made of a semiconductor material such as Si. The sensor chip 3 includes a sensor part (not shown) which outputs a signal corresponding to one physical quantity such as pressure, acceleration, angular velocity or the like; the sensor part, which may be also referred to as a sensor, is formed on the one side face 3a. The sensor chip 3 is manufactured by a semiconductor process. The sensor chip 3 includes an electrode pad (not shown) formed on the one side face 3a; as shown in FIG. 1, a wire 4 is connected to the electrode pad.

In addition, for example, when outputting a signal corresponding to the pressure, the sensor part is configured to include a diaphragm or a gauge resistance. The sensor part has a configuration according to the physical quantity to be detected.

The wire 4 is a member for electrically connecting the sensor chip 3 with other members, and is made of a conductive metal material such as aluminum or gold, for example, and is connected using wire bonding. In the present embodiment, the wire 4 electrically connects the sensor chip 3 with the support member 1. However, the sensor chip 3 may be electrically connected to another member (not shown). The number of wires 4 and the connecting part may be appropriately changed according to the purpose of the physical quantity sensor.

The above is a basic configuration of the physical quantity sensor of the present embodiment. The physical quantity sensor of the present embodiment is, for example, a pressure sensor, an acceleration sensor, a gyro sensor or the like depending on the type of the sensor chip 3, and may include other members or the like (not shown) according to the purpose.

Next, the effect of the modified adhesive layer 21 exhibiting a dilatancy property will be described.

When the wire 4 is connected to the sensor chip 3 by wire bonding such as ultrasonic pressurization or the like, the modified adhesive layer 21 exhibits a high elasticity and is not easily deformed; this prevents the force applied to the sensor chip 3 from escaping to the outside and provides an effect to stabilize the wire bonding.

On the other hand, after the wire 4 is connected, the modified adhesive layer 21 exhibits a low elasticity and is in a soft state. Here, suppose cases that the physical quantity sensor of this embodiment is exposed to an environment in which a temperature change such as a cooling/heating cycle occurs. In such cases, for example, in the sensor chip 3 mainly made of Si, a thermal stress is generated due to a difference in linear expansion coefficient between the sensor chip 3 and the support member 1 made of, for example, a resin material. However, as described above, the modified adhesive layer 21 exhibits a low elasticity and is in a soft state after connection of the wire 4, that is, in a situation where no sudden external force is applied. Thereby the thermal stress applied to the sensor chip 3 is alleviated and the reliability is ensured.

That is, the modified adhesive layer 21 exhibits a high elasticity to be hard at the time of wire bonding of the wire 4, while exhibiting a low elasticity to be soft in a state after the wire bonding. This provides a configuration ensuring both the stability of wire bonding and the reliability by alleviating thermal stress on the sensor chip 3.

According to the study of the inventors of the present disclosure, the reduction in the sinking of the sensor chip 3 into the adhesive layer 2 (hereinafter referred to as “chip amplitude”) when the wire 4 is connected to the sensor chip 3 disposed on the adhesive layer 2 provides a tendency that improves the stability of the wire bonding. Specifically, according to the study of the present inventors, the chip amplitude is inversely proportional to each of (i) the contact area between the sensor chip 3 and the adhesive layer 2 and (ii) the elastic modulus of the adhesive layer 2.

In recent years, there is a need for downsizing the sensor chip 3 with this kind of physical quantity sensor, but miniaturization of the sensor chip 3 may be unsuitably from the viewpoint of stability of wire bonding since the contact area with the adhesive layer 2 becomes small. However, by forming the adhesive layer 2 with the modified adhesive layer 21 exhibiting a dilatancy property, the elastic modulus of the adhesive layer 2 at the time of wire bonding can be increased and the chip amplitude can be reduced. Therefore, even if the sensor chip 3 is downsized, the physical quantity sensor of the present embodiment is also expected to have an effect that ensures the stability of wire bonding more than before.

Next, an example of the method of manufacturing the physical quantity sensor of this embodiment will be described. However, except for the fact that the adhesive layer 2 is formed as the modified adhesive layer 21 including a dilatant fluid, the same manufacturing method as that of this kind of conventional physical quantity sensor can be adopted. Thus, the steps other than the step of forming the adhesive layer 2 will be briefly described here.

For example, a resin molded body formed by compression molding or the like is prepared as the support member 1. A dilatant fluid is applied onto the front side face 1a of the resin molded body with, for example, a dispenser to form the adhesive layer 2. The dilatant fluid is obtained, for example, by mixing a low elasticity material such as silicone and a highly elasticity material such as SiO₂ at a predetermined ratio and stirring.

Subsequently, a sensor chip 3 manufactured by a semiconductor process is prepared. The sensor chip 3 is placed on the adhesive layer 2 so that the opposite side face 3b opposite to the one side face 3a faces the adhesive layer 2. Thereafter, the wire 4 is connected to (i) the one side face 3a of the sensor chip 3 and (ii) the support member 1, by wire bonding with ultrasonic pressure application, for instance. Finally, for example, by removing excess solvent and the like contained in the adhesive layer 2 by heating and drying, the physical quantity sensor of this embodiment can be manufactured.

Note that the above-described manufacturing method is merely an example and may be appropriately changed; for instance, drying may be executed before wire bonding. For example, suppose cases that the adhesive layer 2 is dried before wire bonding. In such cases, heating and drying may remove the excess solvent or the like contained in the adhesive layer 2 or may promote the connection between the support member 1 and the sensor chip 3. Thereafter, the wire 4 is connected to the sensor chip 3 by wire bonding in the same manner as described above.

According to the present embodiment, a physical quantity sensor includes an adhesive layer 2 which is made entirely of the modified adhesive layer 21 which exhibits a high elasticity at the time of wire bonding and a low elasticity after wire bonding. This achieves a physical quantity sensor that can provide both ensuring stability in wire bonding and ensuring reliability by alleviating thermal stress. In addition, the physical quantity sensor of this embodiment is a physical quantity sensor that can ensure the stability of wire bonding more than before, even if the sensor chip 3 is downsized.

### Second Embodiment

The physical quantity sensor of the second embodiment will be described with reference to FIG. 3. In FIG. 3, as in FIG. 1, the thickness and dimensions are exaggerated and deformed.

As shown in FIG. 3, the physical quantity sensor of this embodiment is different from the first embodiment in that the adhesive layer 2 includes (i) a dilatancy portion 211 exhibiting a dilatancy property and (ii) a low elasticity adhesive 22. In the present embodiment, this difference will be mainly described.

In this embodiment, as shown in FIG. 3, the adhesive layer 2 includes a plurality of dilatancy portions 211 and a low elasticity adhesive 22. For example, the adhesive layer 2 is formed by applying collectively the plurality of dilatancy portions 211 and the low elasticity adhesive 22 with a dispenser or the like. In other words, in the present embodiment, the adhesive layer 2 is made of a material that only partially exhibits a dilatancy property.

The dilatancy portion 211 is, for example, a mixture of a high elasticity material and a low elasticity material as in the first embodiment: however, in the present embodiment, the dilatancy portion 211 is not a single layer but a granular shape such as an oblate spherical shape or a long spherical shape. For example, as shown in FIG. 3, the dilatancy portions 211 are separately arranged in the adhesive layer 2; each dilatancy portion 211 is arranged so as to contact both the support member 1 and the sensor chip 3.

Note that the dilatancy portion 211 may be configured such that the adhesive layer 2 does not transmit the external force due to the wire bonding towards the support member 1 at the time of wire bonding performed to the sensor chip 3. All the dilatancy portions 211 thus need not be in contact with both the support member 1 and the sensor chip 3. Further, the shape of each dilatancy portion 211 or the arrangement of the dilatancy portions 211 in the direction of the layer plane of the adhesive layer 2 is freely-selected.

The low elasticity adhesive 22 is made of a material exhibiting (i) a low elasticity of organic type such as silicone, polyacrylate, perfluoropolyether or the like, and (ii) adhesiveness; the low elasticity adhesive 22 is formed as a single layer in which a plurality of dilatancy portions 211 are dispersed. The low elasticity adhesive 22 may employ any low elasticity adhesive used in this kind of conventional physical quantity sensor.

According to this embodiment, the physical quantity sensor is configured to include an adhesive layer 2 functioning as the modified adhesive layer 21 by including the dilatancy portions 211 and the low elasticity adhesive 22. Even such a configuration may achieve a physical quantity sensor that can provide the same effect as the first embodiment.

### Third Embodiment

The physical quantity sensor of a third embodiment will be described with reference to FIG. 4. In FIG. 4, similarly to FIG. 1, the thickness and dimensions are exaggerated and deformed.

As shown in FIG. 4, the physical quantity sensor according to the present embodiment is different from the first embodiment in that (i) the adhesive layer 2 is configured to include a modified adhesive layer 21 and a low elasticity adhesive 22, and (ii) the modified adhesive layer 21 is arranged immediately below the area of the sensor chip 3 to which the wire 4 is connected in a cross-sectional view. In the present embodiment, this difference will be mainly described.

In this embodiment, as shown in FIG. 4, the adhesive layer 2 is configured to include (i) a modified adhesive layer 21 disposed at a predetermined position and (ii) a low elasticity adhesive 22. For example, it can be obtained by separately applying (i.e., coating) and forming the modified adhesive layer 21 and the low elasticity adhesive 22 with a dispenser or the like.

In the present embodiment, for example, as shown in FIG. 4, the modified adhesive layer 21 is arranged in the area of the adhesive layer 2 immediately below the area to which the wire 4 is connected, as viewed from the direction normal to the one side face 3a of the sensor chip 3, that is, in the direction normal to the one side face 3a.

Hereinafter, for the sake of simplicity of explanation, the followings are defined as follows: a portion of the one side face 3a of the sensor chip 3 to which the wire 4 is connected is referred to as a “wire connection portion”; an area of the one side face 3a adjacent to or surrounding the wire connection portion is defined as a “wire adjacent area”; and a region including the wire connection portion and the wire adjacent area is collectively referred to as a “wire connection region”.

The modified adhesive layer 21 is disposed in a region of the adhesive layer 2 to which the outer periphery of the wire connection region of the one side face 3a of the sensor chip 3 is projected as viewed from the direction normal to the one side face 3a. In other words, as shown in FIG. 4, the modified adhesive layer 21 is disposed in parallel with the wire connection region in a cross-sectional view. This configuration achieves the adhesive layer 2 which helps prevent the force applied to the wire connection portion from escaping to the support member 1, contributing to ensuring the stability of the wire bonding.

Note that the area (i.e., dimension of the area) of the wire connection region as viewed from the direction normal to the one side face may be freely-selected and may be defined to a degree that the stability of wire bonding can be ensured.

In the present embodiment, the low elasticity adhesive 22 is disposed in the remaining portion in the adhesive layer 2 different from the portion where the modified adhesive layer 21 is disposed.

According to the present embodiment, a physical quantity sensor can provide the same effect as the first embodiment.

### Fourth Embodiment

The physical quantity sensor according to a fourth embodiment will be described with reference to FIG. 5. In FIG. 5, similarly to FIG. 1, the thickness and dimensions are exaggerated and deformed.

The physical quantity sensor of this embodiment is different from the first embodiment in that, as shown in FIG. 5, (i) the adhesive layer 2 is configured to include a modified adhesive layer 21 and a low elasticity adhesive 22, and (ii) the support member 1, the low elasticity adhesive 22, and the modified adhesive layer 21 are stacked or layered in sequence in this order from the lower side, while the low elasticity adhesive 22 and the modified adhesive layer 21 form the adhesive layer 2 having a two-layer structure. In the present embodiment, this difference will be mainly described.

In the present embodiment, as shown in FIG. 5, on the front side face 1a of the support member 1, the low elasticity adhesive 22 and the modified adhesive layer 21 are stacked in this order from the lower side, while the low elasticity adhesive 22 and the modified adhesive layer 21 form a two-layer structure included in the adhesive layer 2. In other words, the adhesive layer 2 has a two-layer structure in which two different layers are laminated, and one layer thereof is the modified adhesive layer 21. The adhesive layer 2 is obtained by, for example, coating and forming a low elasticity adhesive 22 with a dispenser or the like and then coating and forming a modified adhesive layer 21 on the low elasticity adhesive 22.

As shown in FIG. 5, the modified adhesive layer 21 is disposed on the low elasticity adhesive 22 in a cross-sectional view and is disposed immediately below the sensor chip 3 so as to be in contact with the opposite side face 3b that is opposite the one side face 3a of the sensor chip 3.

As shown in FIG. 5, the low elasticity adhesive 22 is layered on the front side face 1a of the support member 1.

According to the present embodiment, the modified adhesive layer 21 exhibiting a dilatancy property is disposed directly under the sensor chip 3; a physical quantity sensor is provided as having an adhesive layer 2 capable of ensuring the stability of wire bonding and ensuring reliability by relaxing thermal stress applied to the sensor chip 3. Therefore, the physical quantity sensor according to the present embodiment can provide the same effect as the first embodiment.

### Modified Example of Fourth Embodiment

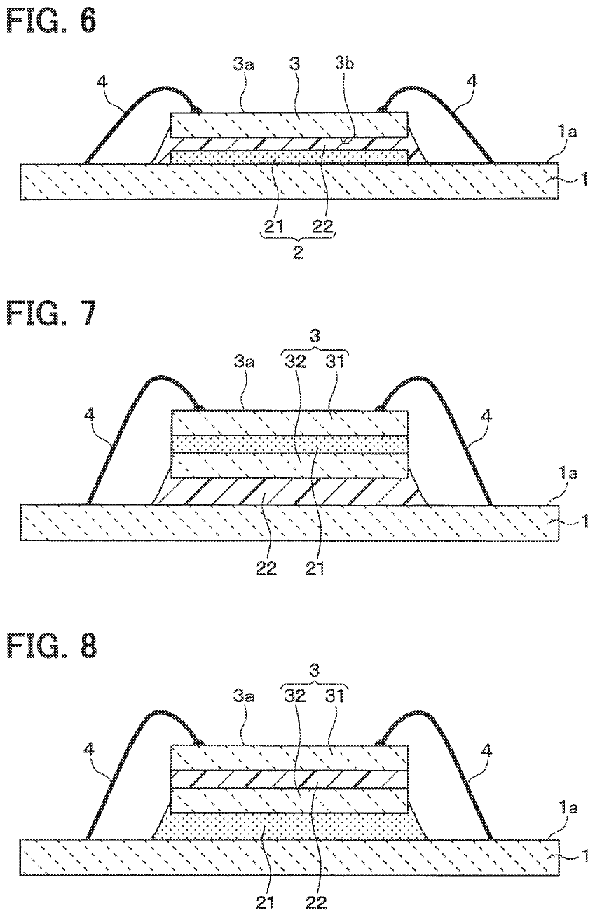

A modified example of the physical quantity sensor of the fourth embodiment will be described with reference to FIG. 6. In FIG. 6, similarly to FIG. 1, the thickness and dimensions are exaggerated and deformed.

This modified example is different from the fourth embodiment in that, as shown in FIG. 6, in the adhesive layer 2, the modified adhesive layer 21 and the low elasticity adhesive 22 are stacked in this order from the lower side. In this modified example, for example, the adhesive layer 2 is obtained by coating and forming the modified adhesive layer 21 and the low elasticity adhesive 22 in this order, contrary to the above-described fourth embodiment, by a dispenser or the like.

Under such a configuration, as shown in FIG. 6, since the modified adhesive layer 21 is formed beforehand in the area immediately under the sensor chip 3, the thickness of the low elasticity adhesive 22 is thin. The low elasticity adhesive 22 directly under the wire connection region of the sensor chip 3 is thin and the modified adhesive layer 21 is disposed to be closer to the support member 1 than the low elasticity adhesive 22. This achieves the formation of the adhesive layer 2 which helps prevent the external force applied to the sensor chip 3 during wire bonding from escaping.

Also the physical quantity sensor of this modification example can provide the same effect as that of the above-described fourth embodiment.

### Fifth Embodiment

The physical quantity sensor of a fifth embodiment will be described with reference to FIG. 7. In FIG. 7, as in FIG. 1, the thickness and dimensions are exaggerated and deformed.

As shown in FIG. 7, the physical quantity sensor of this embodiment includes (i) a first substrate 31 having a sensor part (not shown) for outputting a signal corresponding to a physical quantity of the sensor chip 3, and (ii) a second substrate 32; the second substrate 32 and the first substrate 31 are stacked in this order from the lower side to the upper side in FIG. 7, with the modified adhesive layer 21 interposed therebetween. Further, in the physical quantity sensor of the present embodiment, the sensor chip 3 is mounted to the support member 1 such that the second substrate 32 is arranged to face the front side face 1a of the support member 1 via the low elasticity adhesive 22. Further, in the physical quantity sensor of this embodiment, the side face of the first substrate 31 opposite to the side face facing the modified adhesive layer 21 is defined as the one side face 3a; the wire 4 is connected to the one side face 3a. The physical quantity sensor of this embodiment has a difference from the first embodiment in the above point. In the present embodiment, such a difference will be mainly described.

The first substrate 31 and the second substrate 32 are, for example, mainly configured to be made of a semiconductor material such as Si. As shown in FIG. 7, the sensor chip 3 is formed by the first substrate 31 and the second substrate 32 being laminated via the modified adhesive layer 21. In the present embodiment, the sensor chip 3 is configured to function as an acceleration sensor or an angular velocity sensor that outputs a signal corresponding to acceleration or angular velocity, for example.

With such a configuration, when the wire 4 is connected to the one side face 3a of the first substrate 31 by wire bonding, the modified adhesive layer 21 disposed directly under the first substrate 31 in a cross-sectional view exhibits a high elasticity to help prevent the force applied to the first substrate 31 from escaping. That is, the physical quantity sensor of the present embodiment has a structure capable of ensuring the stability in the wire bonding of the wire 4. On the other hand, when thermal stress is applied to the first substrate 31, the modified adhesive layer 21 exhibits a low elasticity, so that this thermal stress is alleviated by the modified adhesive layer 21, providing a structure capable of ensuring reliability.

The present embodiment can achieve a physical quantity sensor that provides the same effect as the first embodiment.

### Modified Example of Fifth Embodiment

A modified example of the physical quantity sensor of the fifth embodiment will be described with reference to FIG. 8. In FIG. 8, similarly to FIG. 1, the thickness and dimensions are exaggerated and deformed.

This modified example is different from the fifth embodiment in that, as shown in FIG. 8, the adhesive layer 2 is configured such that the vertical arrangement of the modified adhesive layer 21 and the low elasticity adhesive 22 is reversed from that of the above-described fifth embodiment.

Even with such a configuration, as shown in FIG. 8, the modified adhesive layer 21 is disposed immediately under the sensor chip 3, that is, in the area directly under the second substrate 32; this suppresses the external force applied to the sensor chip 3 at the time of wire bonding from escaping.

Also in the physical quantity sensor of this modified example, the same effect as that of the fifth embodiment can be provided.

### Other Embodiments

Note that the physical quantity sensor described in each of the above-described embodiments is an example of the physical quantity sensor of the present disclosure, and is not limited to each of the above-described embodiments, and may be appropriately changed within the scope of the present disclosure.

(1) For example, each of the above embodiments describes, as an example, a physical quantity sensor having a structure in which the sensor chip 3 having a sensor part (not shown) is exposed to the outside. The sensor chip 3 may however be covered with a low elasticity material such as silicon gel depending on an intended use of the physical quantity sensor.

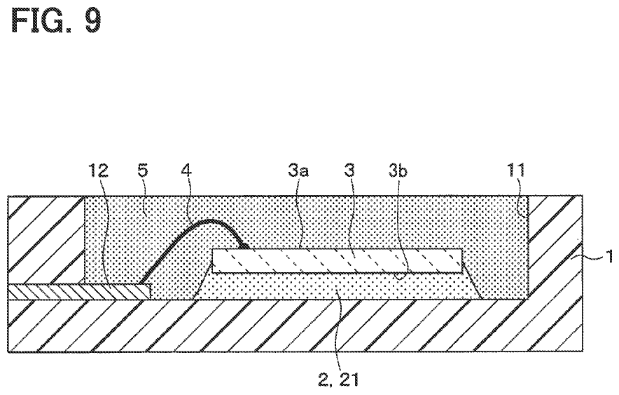

Specifically, for example, when the physical quantity sensor is configured as a pressure sensor, as shown in FIG. 9, the adhesive layer 2, the sensor chip 3, and the wire 4 may be configured to be covered with a low elasticity material 5 such as a silicon gel. In this case, for example, as shown in FIG. 9, the support member 1 is a resin molded body having a recess 11 and an internal wiring 12, while the sensor chip 3 is disposed to the bottom of the recess 11 via the adhesive layer 2. The wire 4 is connected to the one side face 3a of the sensor chip 3, while the sensor chip 3 is electrically connected through the wire 4 to the internal wiring 12 that is disposed on the bottom side of the recess 11; one end of the internal wiring 12 is exposed from the resin molded body (i.e., the support member 1). In such a configuration, the low elasticity material 5 fills the recess 11 and covers the adhesive layer 2, the sensor chip 3, and the wire 4. In this case, when external pressure is applied to the low elasticity material 5, the low elasticity material 5 is deformed and the sensor part (not shown) of the sensor chip 3 outputs a signal corresponding to the deformation. In this manner, the sensor chip 3 may be covered with a low elasticity material or the like to such an extent that it does not interfere with the operation of the sensor part (not shown).

(2) The fifth embodiment and its modified example describe an example in which the modified adhesive layer 21 for supporting the first substrate 31 or the second substrate 32 is formed as a dilatant fluid as in the first embodiment.

However, the configuration of the adhesive layer 2 in the second to fourth embodiments may be adopted in the modified adhesive layer 21 of the fifth embodiment.

(3) Each of the above-described embodiments describes, as an example, a physical quantity sensor that includes the sensor chip 3 provided with a sensor part that outputs an electric signal corresponding to the physical quantity. The sensor chip 3 may however be a semiconductor chip that does not include the above-described sensor part. For example, a semiconductor device may be employed in which a circuit chip (i.e., a semiconductor chip having an IC instead of the sensor chip 3) is mounted to the support member 1 via the adhesive layer 2 while the wire 4 is connected to the circuit chip. This achieves a semiconductor device which ensures stability in wire bonding and stress relaxation thereafter. Note that the structure of this semiconductor device is basically the same as the structures shown in FIGS. 1 and 3 to 8 in the above embodiments, except that only the sensor chip 3 is replaced by a circuit chip.

In addition, when thermal stress acts on the circuit chip, the wiring of the circuit chip is minutely deformed, and there is a possibility that the electric characteristics of the circuit may fluctuate due to the piezo effect. This electric characteristic fluctuation is however supposed to be suppressed by the adhesive layer 2 providing the stress relaxation after wire bonding. It is also expected that a semiconductor device having a circuit chip mounted thereto via an adhesive layer 2 having a material exhibiting a dilatancy property has a structure for suppressing fluctuation in electric characteristics due to thermal stress. Likewise, the physical quantity sensor of each of the above-described embodiments is also expected to have the effect of suppressing variation in electric characteristics due to relaxation of thermal stress.

For reference to further explain features of the present disclosure, a comparative technique is described as follows. There is a comparative physical quantity sensor which includes (i) a sensor chip having a sensor part for outputting a signal corresponding to a physical quantity, (ii) a support member on which the sensor chip is mounted, (iii) an adhesive layer disposed on the support member and supporting the sensor chip, and (iv) a wire to be electrically connected to the sensor chip.

Such a physical quantity sensor has a configuration where a sensor chip having a sensor part is mounted on a substrate as a support member with an adhesive layer interposed therebetween, and a wire is electrically connected to the sensor chip on one side face of the sensor chip opposite the other side face facing the adhesive layer.

A physical quantity sensor of this type can be obtained, for example, by applying a coating solution containing an adhesive material on a prepared support member to form an adhesive layer, mounting the sensor chip on the adhesive layer, and then performing wire bonding of a wire to the sensor chip to be electrically connected to each other.

Here, when wire bonding is performed by a method such as ultrasonic pressurization, in order to stabilize wire bonding, it is preferable that the energy of ultrasonic waves is transmitted to the sensor chip does not escape through the adhesive layer. In other words, from the viewpoint of ensuring the stability of wire bonding, it is preferable that the adhesive layer is made of a material which is less deformable to prevent the energy transmitted to the sensor chip from escaping from the sensor chip. That is, it is preferable that the adhesive layer is made of a hard material having a high elasticity.

On the other hand, in this type of physical quantity sensor, the support member and the sensor chip are made of materials having different linear expansion coefficients; when a temperature change occurs, the thermal stress due to the difference in linear expansion coefficient arises in the sensor chip via the adhesive layer. In order to alleviate the thermal stress caused by the difference in the linear expansion coefficient between the support member and the sensor chip and to ensure the reliability, it is preferable that the adhesive layer is made of a material which is easily deformed elastically, and less likely transmits the deformation due to heat of the support member to the sensor chip. That is, it is preferably that the adhesive layer is configured to include a soft material having a low elasticity.

In other words, the adhesion layer used for this type of physical quantity sensor is required to have opposite characteristics in terms of ensuring the stability of wire bonding and ensuring the reliability in temperature change; it is difficult to satisfy both of such requirements. This is not limited to the case where the sensor chip is mounted, and the same applies to a semiconductor device using a semiconductor chip that does not output an electrical signal corresponding to the physical quantity.

It is therefore desired to provide a physical quantity sensor and a semiconductor device, each of which includes an adhesive layer capable of achieving both stability in wire bonding and reliability in temperature change.

Aspects of the disclosure described herein are set forth in the following clauses.

A first aspect of the present disclosure, a physical quantity sensor is provided to include (i) a sensor chip having a sensor part that outputs a signal corresponding to a physical quantity, (ii) a support member to which the sensor chip is mounted, (iii) an adhesive layer disposed on a side face of the support member to support the sensor chip, and (iv) a wire electrically connected to the sensor chip on a side face of the sensor chip opposite to the adhesive layer. The adhesive layer includes a material exhibiting a dilatancy property in which a shear stress increases in a multi-dimensional function as a shear rate increases.

In such a configuration, the adhesive layer has a material exhibiting a dilatancy property that the shear stress increases in a multi-dimensional function as the shear rate increases.

As a result, the physical quantity sensor is provided with an adhesive layer having a material exhibiting a dilatancy property such that the shear stress becomes greater in a multi-dimensional function when a greater shear rate is applied. Therefore, when a great shear rate (i.e., a sudden external force) is applied, the adhesive layer supporting the sensor chip exhibits a high shear stress, that is, a high elasticity which is a hard property; when a small shear rate is applied, the adhesive layer exhibits a low elasticity which is a soft property.

The adhesive layer is thus provided to exhibit a high elasticity when a sudden external force due to wire bonding is applied to the sensor chip, and to exhibit a low elasticity after wire bonding is performed. This achieves is a physical quantity sensor that ensures stability in wire bonding and reliability by alleviating thermal stress.

According to a second aspect of the present disclosure, a semiconductor device is provided to include (i) a circuit chip, (ii) a support member to which the circuit chip is mounted, an adhesive layer disposed on a side face of the support member to support the circuit chip, and wire electrically connected to the circuit chip on a side face of the circuit chip opposite to the adhesive layer. The adhesive layer includes a material exhibiting a dilatancy property in which a shear stress increases in a multi-dimensional function as a shear rate increases.

The above configuration of the second aspect may provide a semiconductor device, in which, similarly to the physical quantity sensor according to the first aspect, it is possible to ensure both stability in wire bonding and reliability by alleviating thermal stress, and alleviating the thermal stress applied to the circuit chip suppresses variations in electrical characteristics of the circuit.

1. A physical quantity sensor comprising:
a sensor chip having a sensor that outputs a signal corresponding to a physical quantity;
a support member to which the sensor chip is mounted;
an adhesive layer disposed on a side face of the support member, the adhesive layer supporting the sensor chip; and
a wire electrically connected to the sensor chip on a side face of the sensor chip, the side face of the sensor chip being opposite to the adhesive layer, wherein:
on the side face of the sensor chip, a wire connection region is defined as including (i) a portion to which the wire is connected and (ii) an area adjacent to the portion to which the wire is connected;
a projection of the wire connection region into the adhesive layer via the sensor chip as viewed from a direction normal to the side face of the sensor chip is defined as a projection portion in the adhesive layer; and
the adhesive layer includes (i) a modified adhesive that includes a material exhibiting a dilatancy property in which a shear stress increases in a multi-dimensional function as a shear rate increases, and (ii) a low elasticity adhesive that includes a low elasticity material; and
the modified adhesive is arranged as the projection portion in the adhesive layer, whereas the low elastic adhesive is arranged as a remaining portion of the adhesive layer other than the projection portion.

2. The physical quantity sensor according to claim 1, wherein:
the modified adhesive includes a mixture of a high elasticity material and a low elasticity material.

3-8. (canceled)
